(19) United States
(12) Patent Application Publication
(10) Pub. No.: US 2025/0011157 A1
(43) Pub. Date: Jan. 9, 2025

(54) MICROMECHANICAL COMPONENT AND METHOD FOR PRODUCING SAME

(71) Applicants: Fraunhofer-Gesellschaft zur Förderung der angewandten Forschung e.V., München (DE); OQMENTED GMBH, Itzehoe (DE)

(72) Inventors: Frank Senger, Hardenfeld (DE); Stephan MARAUSKA, Kaltenkirchen (DE); Ulrich Hofmann, ltzehoe (DE); Gunnar WILLE, ltzehoe (DE); Fabian SCHWARZ, ltzehoe (DE)

(21) Appl. No.: 18/710,597

(22) PCT Filed: Nov. 18, 2022
(86) PCT No.: PCT/EP2022/082478

§ 371 Date: May 15, 2024

(30) Foreign Application Priority Data
Nov. 19, 2021 (DE) 10 2021 213 028.3

(51) Int. Cl. B81B 3/00; B81C 1/00; G02B 26/08; H02N 2/18

(52) U.S. Cl. CPC B81B 3/0021; B81C 1/00349; G02B 26/0858; H02N 2/188; B81B 2201/042; B81B 2203/0163; B81B 2203/04; B81C 2201/0105; B81C 2201/013; B81C 2201/016; B81C 2201/0181; B81C 2201/0198

(57) ABSTRACT

The present application relates to a micromechanical component (1) and a method for producing a micromechanical component (1). The proposed micromechanical component (1) comprises a layered structure and at least one piezoelectric element (10). The piezoelectric element (10) contains a first electrode (5) and second electrode (27) for generating and/or detecting deflections of a deflection element (16). The deflection element (16) is connected to a holder (17). The layered structure of the micromechanical component (1) comprises a silicon substrate (2), a conductive semiconductor layer (26), a piezoelectric layer (7) and a conductive layer film (12). The conductive semiconductor layer (26) forms the first electrode (5) and the conductive layer film (12) forms the second electrode (27) of the piezoelectric element, wherein the conductive semiconductor layer (26) at the same time forms a carrier layer (28) for the deflection element (16).

The present application lies in the field of microsystems. The application relates to a micromechanical component, in particular a MEMS component based on the piezo effect (MEMS=Micro electro mechanical system) and to a method for production of same.

In general, micromechanical components may be used as a MEMS mirror scanner in areas such as augmented reality displays, light detection and ranging devices (LIDAR) or 3D cameras. Further applications may be found in the areas of micropumps and energy harvesters.

Characteristic features of a micromechanical component are its compact size and low energy requirement.

MEMS mirror scanners are configured to deflect an incoming optical beam and/or cause a phase shift in a corresponding electromagnetic wave. A deflection and/or phase shift of the incoming electromagnetic wave may be caused by tilting and/or rotation of a micromirror contained in the MEMS mirror scanner. There are various methods for controlling a MEMS mirror scanner in order to tilt and/or rotate a micromirror. Piezoelectric control based on the deformation of a piezoelectric body is very promising, as piezoelectric bodies may be controlled very precisely, generate force efficiently by converting electrical energy into mechanical deflection and therefore generally have low power consumption and may be easily integrated monolithically into a MEMS component. The related prior art is described, for example, in the publication US 2009/185 253 A1.

The publication US 2009/185 253 A1 describes an optical reflector containing a mirror with a reflecting plane, a torsion bar and a carrier surrounding the mirror. For a piezoelectric element configured to cause torsion, a first electrode layer, a piezoelectric layer and a second electrode layer are formed in series on the upper surface of an SOI substrate. The material used for the first electrode layer is, for example, Ti for a first thin metal film layer and Pt for a second thin metal film layer. Each metal layer is formed by sputtering or an electron beam physical vapour deposition technique. Next, the piezoelectric layer is formed on the first electrode layer, which consists of a single film of piezoelectric material, for example. The piezoelectric material lead zirconate titanate (PZT) may be used as the material for the piezoelectric layer. The thickness of the piezoelectric layer is typically 1-10 μm. The piezoelectric layer is formed by cathode sputtering, for example.

U.S. Pat. No. 8,633,634 B2 describes a micromechanical component that is formed as a flexural resonator and serves as an energy harvester. To produce this micromechanical component, a sacrificial layer is first applied to a silicon substrate, onto which a layered structure is then deposited, comprising a piezoelectric layer and a functional layer underneath, which forms the mechanical carrier for the piezoelectric layer. In order to expose the bending beam, which consists of a functional layer and a piezoelectric layer, among other things, so that it may move mechanically, the previously applied sacrificial layer is laboriously removed. The sensitivity of the piezoelectric material to various physical process variables, such as temperature, acid, alkali, but also hydrogen, must be taken into account, and what must be aimed for is a reduction of the process steps carried out, such as additional lithography levels as well as depositions and etchings.

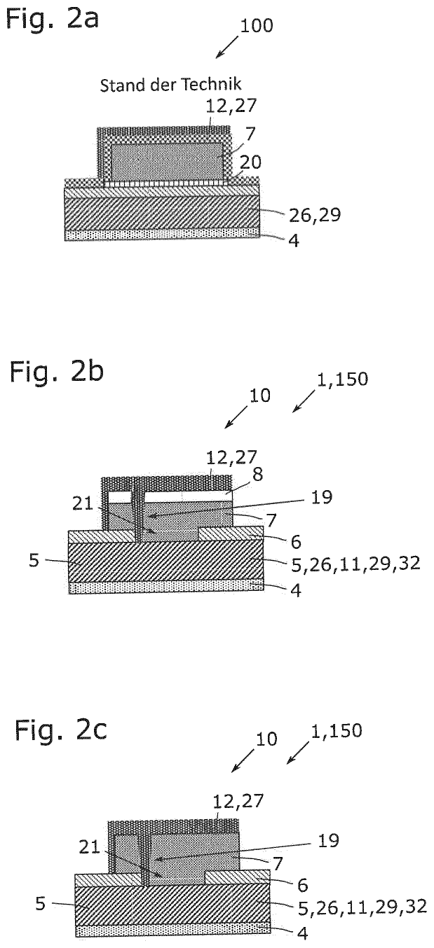

A disadvantage of many micromechanical components known from the prior art is that a large number of growth, vapour deposition, sputtering and lithography steps are required to form the individual components, such as a deflection element, a holder, piezoelectric elements, including a first and second electrode and a suspension mechanically connected to the holder and the deflection element. FIG. 2a shows, as an exemplary embodiment of a micromechanical component, a cross-section through a part of a conventional piezoelectrically driven MEMS mirror scanner 100 with a metal first electrode 20.

Accordingly, the object of the present invention is to propose a micromechanical component with reduced manufacturing complexity that conserves resources and reduces costs. A further object is to propose a corresponding advantageous method for producing a micromechanical component in which the method steps are simplified.

The problem is solved by a micromechanical component having the features of claim 1 and by a method for producing a micromechanical component having the features of the independent method claim. Developments result from the features of the dependent claims and the exemplary embodiments.

The proposed micromechanical component is adaptable to a wide variety of applications, for example it may be used as a MEMS mirror scanner, acceleration sensor, energy harvester, pressure sensor and the like. If desired, large actuator and/or sensor surfaces may be realized and wide component cross-sections may be provided, which may be used for better heat dissipation if necessary.

The micromechanical component has a layered structure and at least one piezoelectric element containing a first electrode and a second electrode for generating and/or detecting deflections of a deflection element. The deflection element is connected to a holder. The layered structure comprises a silicon substrate, a conductive semiconductor layer, a piezoelectric layer and a conductive layer film. The conductive semiconductor layer forms the first electrode and the conductive layer film forms the second electrode of the piezoelectric element. The semiconductor layer also serves as a carrier layer for the deflection element.

As a rule, the micromechanical component is produced by layering metals, semiconductors and/or insulators on a substrate, in particular a silicon substrate or a silicon on insulator (SOI) substrate, and by subsequent structuring to form the deflection element, a suspension, the holder and the piezoelectric elements. As already introduced above, the second electrode of the piezoelectric element consists of a metal and/or a metal alloy, in particular Al, Cr, Cu, Mo, Ta, Au, Pt or Ti, and the first electrode, which is also the carrier layer of the deflection element, consists of a semiconductor material, in particular Si.

The fact that the conductive semiconductor layer forms both the first electrode and the carrier layer of the deflection element means that the complexity of the production of the micromechanical component may be reduced, as additional deposition, lithography, etching and resistance removal steps for forming the first electrode may be dispensed with, for example. Semiconductor materials may achieve high conductivity at room temperature due to their small band gap and the possibility of doping, so that the micromechanical component may have a low electrical operating voltage. Due to high crystal field energies, semiconductor materials also have high rigidity and may be used favourably as carrier layers. It may be envisaged to use semiconductor materials such as Si, SIC, AlN, GaN, InN, AIP, GaP, InP, AlAs, GaAs, InAs and the associated ternary compound semiconductors as the first electrode. For high conductivity, the semiconductor material may be n-doped, p-doped or intrinsic. In particular, the first electrode may consist of doped polycrystalline silicon.

In an advantageous way, the thickness of the conductive semiconductor layer may be adjusted depending on predetermined mechanical and electrical parameters and may be adapted to the desired mechanical behaviour of the micromechanical component. When producing a specific micromechanical component, it is possible to determine and specify the mechanical behaviour of the component in advance based on the thickness of the conductive semiconductor layer. On the other hand, by thinning the conductive semiconductor layer at the end of the process chain, it is subsequently possible to adapt the mechanical properties to application requirements. By adjusting the thickness of the conductive semiconductor layer, for example, the resonant frequency of a micromechanical component formed as a MEMS mirror scanner may be adjusted or the deflection of a micromechanical component formed as a beam element may be determined.

In further embodiments, the conductive semiconductor layer, the piezoelectric layer and the conductive layer film may be formed in layers in different layer planes, wherein they have a layer sequence of the following type starting from one side of the silicon substrate:
conductive semiconductor layer,
piezoelectric layer,
conductive layer film.

Further semiconductor, insulator and/or metal layers may be inserted between the layers. Accordingly, a distance between the conductive semiconductor layer and the silicon substrate, which is measured perpendicular to a silicon substrate plane, is smaller than a distance between the silicon substrate and the piezoelectric layer, which in turn is smaller than a distance between the silicon substrate and the conductive layer film. In this way, the piezoelectric layer may be advantageously supplied with electrical voltage in order to cause a piezoelectric change in the shape of the piezoelectric layer. Alternatively, an electrical voltage generated by a change in the shape of the piezoelectric layer may be efficiently tapped or applied in this way.

The piezoelectric layer may lie directly on the conductive semiconductor layer. Furthermore, a passivation layer may be arranged on the piezoelectric layer, at least in some regions. The conductive layer film forming the second electrode may lie on the passivation layer. It may be expedient to wrap the second electrode in a hard dielectric film for stability reasons.

It is possible that the micromechanical component is formed as a piezoelectrically driven MEMS mirror scanner. The deflection element may be a spring structure connected to the holder and a mirror plate suspended from the spring structure, wherein the conductive semiconductor layer simultaneously forms the carrier layer of the mirror plate and/or the spring structure. The spring structure and the suspended mirror plate must be exposed, at least in some regions, in order to enable advantageous and efficient deflection. Normally, a large number of deposition steps, lithography steps, etching steps and resistance removal steps must be used in principle, especially when forming the piezoelectrically driven MEMS mirror scanner. The fact that the conductive semiconductor layer also forms the carrier layer of the mirror plate and/or the spring structure means that the complexity of the production of a piezoelectrically driven MEMS mirror scanner may be reduced.

Furthermore, the conductive layer film may form a light-reflecting mirror layer of the mirror plate. Metals or metal alloys are particularly suitable as the light-reflecting mirror layer of the mirror plate, as metals have a high degree of reflection in the visible and infrared spectral range (wavelengths 400-2000 nm). In turn, a number of production steps—in particular an additional deposition process—may be reduced in order to further simplify the production of the piezoelectrically driven MEMS mirror scanner. However, the advantage of forming the mirror plate, the conductor track(s) and the bond pads from the deposited layer film of, e.g., aluminium in a thickness of, e.g., 400 nm must be weighed against the disadvantage that the mirror plate has the same thickness as the conductor track and the bond pads, which require a certain thickness due to the stability and the desired resistance value. This thickness has a certain disadvantage with the mirror plate, as the roughness, along with a reduction in reflection, and also the layer stress increase. It is therefore necessary to consider whether, after applying the relatively thick metallization for the conductive layer film, e.g. 400 nm aluminium, it should be removed again in the area of the mirror plate and another very thin metal, e.g. 20 nm aluminium, should be applied, which may then be structured at the same time as the “thick” metallization using a lacquer mask.

It may be provided that the spring structure has the conductive semiconductor layer, the piezoelectric layer and the conductive layer film at least in some areas. The conductive semiconductor layer, the piezoelectric layer and the conductive layer film form the piezoelectric element. Using the conductive semiconductor layer and the conductive layer film, the piezoelectric layer may be supplied with electrical voltage to cause a change in shape due to the piezoelectric effect. Because the piezoelectric layer is mechanically connected to the spring structure, a change in the shape of the piezoelectric layer leads to a deflection of the spring structure. This deflection of the spring structure in turn leads to a deflection of the suspended mirror plate.

In further embodiments, the conductive semiconductor layer, the piezoelectric layer and the conductive layer film may be located at positions with small bending radii when the spring structure is deflected. In other words, the piezoelectric element, which is just formed of the conductive semiconductor layer, the piezoelectric layer and the conductive layer film, is located at positions on the spring structure with small curvatures under operation of a spring structure-mirror plate system. Areas with large bending radii, which may be determined by a simulation, in particular a mechanical finite element analysis, should not have a piezoelectric element, in particular to prevent material defect-induced low-resistance connections due to material fatigue. Furthermore, the piezoelectric elements should be located at positions with optimum mechanical stress behaviour, in particular a high positive mechanical stress or high negative mechanical stress. In this way, actuation efficiency and/or detection efficiency may be maximized. Furthermore, the spring structure which connects the holder to the suspended mirror plate may have at least one curved area which, in the resting state, is formed in particular along a plane parallel to the silicon substrate plane.

Furthermore, the deflection element may be formed as a beam element suspended on at least one side. The conductive semiconductor layer also forms the carrier layer of the beam element. In particular, the micromechanical component may be formed as an energy harvester. In contrast to the piezoelectrically driven MEMS mirror scanner, the piezoelectric elements of the energy harvester are not actuated. Rather, the energy harvester, in particular including its deflection element, is set into oscillation, vibration and/or deflection by means of ambient vibration. Sensitivity to different frequency spectra of the ambient vibration may be adjusted by means of the geometry of the energy harvester. The oscillation, vibration and/or deflection of the deflection element is converted into electrical voltage and/or an electrical current on the basis of the piezoelectric elements. This electrical voltage may now be stored in a suitable circuit for later use. However, it is also possible that the electrical voltage obtained is used immediately via a consumer. The fact that the conductive semiconductor layer also forms the carrier layer of the beam element means that the complexity of the production may be reduced.

Furthermore, the beam element may have the conductive semiconductor layer, the piezoelectric layer and the conductive layer film at least in some areas. The conductive semiconductor layer, the piezoelectric layer and the conductive layer film form the piezoelectric elements. Using the conductive semiconductor layer and the conductive layer film, the electrical voltage generated by the piezoelectric layer may be tapped. Because the piezoelectric layer is mechanically connected to the beam element, a deflection of the beam element leads to a change in the shape of the piezoelectric layer. This change in shape leads to the electrical voltage obtained.

In further embodiments, the beam element may comprise the silicon substrate, at least in some areas, which is arranged in such a way that it forms an inertia mass for the beam element. In this way, an inertia mass of the beam element may be increased in order to favourably convert the ambient vibrations into an oscillation, vibration and/or deflection of the beam element. In particular, sensitivity to different frequency spectra of the ambient vibration may be adjusted by means of a weight of the inertial mass.

The micromechanical component may also have at least one dielectric layer between the conductive semiconductor layer and the piezoelectric layer, at least in some areas. The dielectric layer may be formed as an insulator layer that acts as a current diaphragm for the first and second electrodes. It may be provided that the insulator layer is configured to conduct the current to the piezoelectric layer locally and to prevent a low-resistance connection, in particular a short circuit, between the first electrode and the second electrode when the micromechanical component is put into operation. Typical thicknesses of the dielectric layer are between 5 nm and 500 nm, in particular between 10 nm and 150 nm. It is possible that the dielectric layer is formed as a passivation layer.

In other embodiments, the conductive semiconductor layer may be separated from the piezoelectric layer by a dielectric layer covering the entire surface. In this way, the piezoelectric layer may be deposited planar on the dielectric layer. This avoids the disadvantages of depositing the piezoelectric layer on a non-planar dielectric layer that has stepped edges, which may lead to flaws and/or crystal defects, such as pits and/or voids, within the piezoelectric layer, which could result in low-resistance electrical connections and short-circuiting of the micromechanical component. In particular, the low-resistance connections are created by subsequently filling the pits and/or voids with further semiconductor or metal layers.

In other embodiments, an opening region may be provided in the dielectric layer. The opening region is provided by direct contact between the piezoelectric layer and the conductive semiconductor layer. The electrode area of the second electrode of the opening region is smaller than the opening area of the opening region. Flaws and/or crystal defects within the piezoelectric layer occur more frequently in an edge region of the opening region of the dielectric layer. The flaws and/or crystal defects typically continue in a direction perpendicular to a silicon substrate plane. If the second electrode surface is smaller than the opening area of the dielectric layer, the second electrode does not lie directly over the edge area of the opening region of the first electrode. In this way, penetration of a material from the second electrode into the flaws may be prevented. The penetration of the material of the second electrode into the flaw may in turn lead to undesirable low-resistance connections.

It is possible that the opening region of the dielectric layer is filled with silicon. Typically, the thickness of the dielectric layer is identical to the thickness of the silicon layer used for the filling. The openings in the dielectric layer are filled by selective growth. As an alternative to selective growth, lithographic processes may be used to realize the filling of the opening region of the dielectric layer. In this way, the piezoelectric layer may be deposited planar. Analogously to the above, flaws and/or crystal defects within the piezoelectric layer may be avoided in this way, which may occur when the piezoelectric layer is deposited on a non-surface-covering or non-planar layer. The silicon layer may also be doped in order to increase electrical conductivity on the basis of acceptor or donor states. The openings may be filled with p-doped, n-doped or intrinsic silicon. The silicon may be polycrystalline in particular. Furthermore, the opening of the dielectric layer may be filled with other semiconductor materials or metals. High conductivity is advantageous here to prevent a loss of electrical operating voltage.

A layer thickness of the dielectric layer may be thinner than 2000 nm, in particular thinner than 1000 nm and even more preferably thinner than 100 nm. A thin dielectric layer leads to a smaller step height L in the opening region of the dielectric layer compared to a layer underneath. A deposition of the piezoelectric layer on a quasi-full-coverage or quasi-planar dielectric layer may lead to a reduced density of flaws and/or crystal defects within the piezoelectric layer. As a rule, the density and degree of formation, in particular the spatial extent, of the flaws increase with the step height of the dielectric layer in the opening region. However, if the thickness of the dielectric layer is too thin, in particular thinner than 10 nm, tunnelling, drift and/or diffusion currents may lead to leakage currents or voltage breakdowns. Preferably, the thickness of the dielectric layer should be thicker than 1 nm.

Furthermore, the thickness of the dielectric layer may decrease towards the opening region. In this way, a gradient of a step and a maximum step height at the transition between the dielectric layer and the piezoelectric layer may be reduced, in particular down to a step height of a monolayer of the dielectric layer. A deposition of the piezoelectric layer on a dielectric layer, which decreases towards the opening region, may in turn lead to a reduced density and/or degree of formation of flaws within the piezoelectric layer.

It may be provided that the conductive semiconductor layer consists of silicon, in particular polycrystalline silicon. In other embodiments, the conductive semiconductor layer may be made of monocrystalline silicon. Furthermore, the conductive semiconductor layer may be doped. In this way, electrical conductivity may be increased and the electrical operating voltage of the micromechanical component may be reduced. By using polycrystalline silicon, manufacturing costs may be reduced compared to monocrystalline silicon. On the other hand, the use of monocrystalline silicon may improve the mechanical breaking point and thus the mechanical robustness of the micromechanical component.

Furthermore, a passivation layer may be arranged at least partially on the piezoelectric layer. The passivation layer may be insulating. The thickness of the passivation layer is typically between 5 nm and 500 nm. It may be provided that the passivation layer is not parallel to the silicon substrate plane in some areas and in particular covers side walls—for example of the pits or voids or side walls that are given by a geometry of the micromechanical component. In this way, galvanic contact between the first and second electrodes may be prevented, particularly despite the presence of flaws, which may lead to low-resistance connections. A passivation layer that is too thin could lead to leakage currents based on tunnelling, drift, diffusion currents and/or voltage breakdowns. A passivation layer that is too thick may greatly increase the operating voltage of the micromechanical component.

In further embodiments, a metal film may be arranged between the piezoelectric layer and the conductive layer film, at least in some areas. In particular, a high conductivity of the metal film is advantageous in order to avoid a high operating voltage of the micromechanical component. It may be provided that the metal film is set up to serve as a masking layer for a further structuring process. If the metal film is omitted, a sacrificial layer may be used as a masking for the further structuring process, which is then removed.

Furthermore, the holder may be a chip frame of the micromechanical component. In particular, it may be provided that the chip frame comprises the deflection element in a plane parallel to the silicon substrate plane.

The present application also relates to a corresponding advantageous method. In this method for producing a micromechanical component, a conductive semiconductor layer is first deposited on a silicon substrate. A piezoelectric layer and a conductive film serving as a second electrode are then deposited on the piezoelectric layer. Subsequently, a deflection element is structured by a masking process of the silicon substrate, the conductive semiconductor layer, the piezoelectric layer and the conductive layer film by lithographic processes. The conductive semiconductor layer is used as a first electrode for the piezoelectric layer and at the same time as a carrier layer for the deflection element. As above, the complexity of producing the micromechanical component may be reduced in this way, as additional deposition steps, lithography steps, etching steps and resistance removal steps for forming the first electrode may be dispensed with, for example.

It is possible that the deposition of the piezoelectric layer is followed by the deposition of a metal film on the piezoelectric layer. In particular, a high conductivity of the metal film is advantageous in order to avoid a high operating voltage of the micromechanical component.

Furthermore, the metal film may be used as a mask for a subsequent structuring process, in particular a structuring process of the piezoelectric layer. This makes it easy to produce a micromechanical component, wherein the sensitive piezoelectric layer is protected by minimizing the processing steps, such as etching steps, and the use of acids, alkalis and elevated temperatures. As no additional sacrificial layers or functional layers are required, no time-consuming removal of the layers is necessary and production costs are reduced. In this way, the complexity of producing the micromechanical component may be further reduced.

However, it may also be advantageous to dispense with the metal film. In this case, an auxiliary or sacrificial layer may be deposited on the piezoelectric layer after the piezoelectric layer has been deposited. This auxiliary or sacrificial layer may be used as a mask for a later structuring process. In particular, a SiN hard mask may be provided as an auxiliary or sacrificial layer.

Furthermore, after the piezoelectric layer has been deposited, an insulating passivation layer may be deposited on the piezoelectric layer. The thickness of the passivation layer is typically between 5 nm and 500 nm. In this way, galvanic contact between the first and second electrodes may be prevented.

The silicon substrate may be formed as an oxidized silicon substrate, in particular as an SOI substrate. This may improve a process, in particular a process accuracy and/or a layer thickness accuracy of the carrier layer and the conductive semiconductor layer.

Furthermore, the masking process of the substrate may be set up so that the substrate remains at least partially in a region of the deflection element. This allows the deflection element to be stiffened. In particular, this may lead to less deformation of the deflection element. Various structures of the silicon substrate, in particular honeycomb-like structures, may be provided. Furthermore, the entire layer thickness of the deflection element may be varied, in particular to vary the resonance frequency of the micromechanical component.

The features mentioned in relation to the micromechanical component are applicable accordingly to the method for producing the micromechanical component.

Exemplary embodiments of the invention, in particular in the form of MEMS mirror scanners and energy harvesters, are explained below with reference to the figures. In each case schematically,

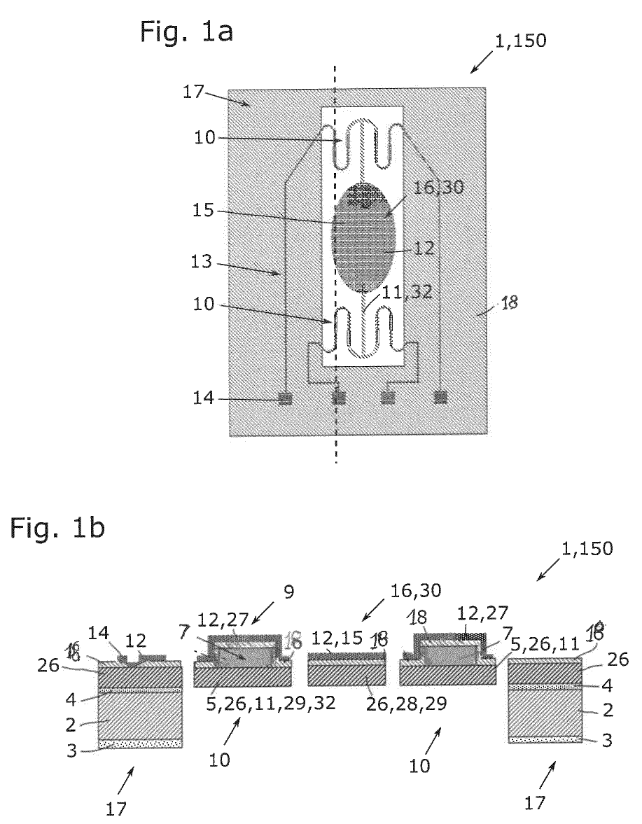

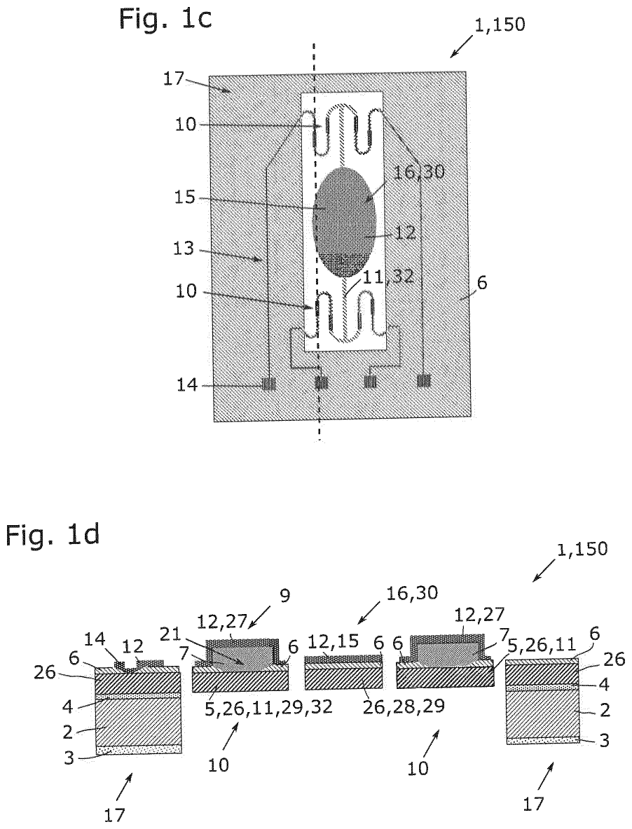

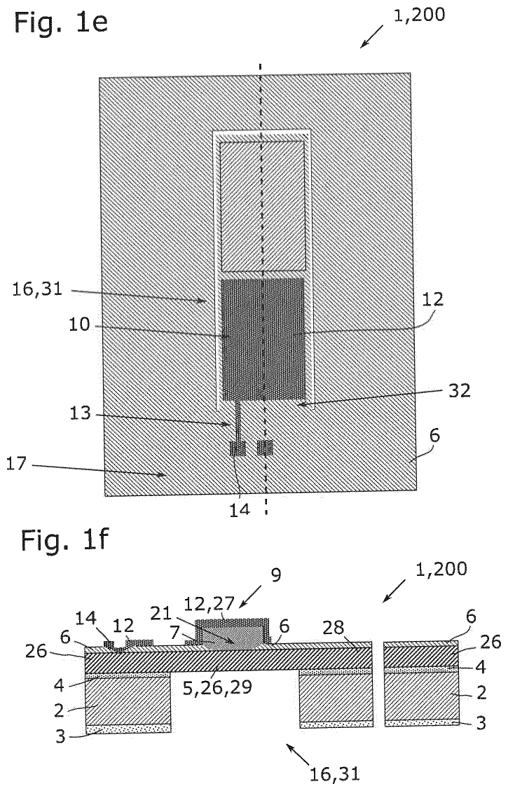

FIG. 1a a plan view of a piezoelectrically driven MEMS mirror scanner according to an exemplary embodiment,

FIG. 1b a cross-section corresponding to a dashed sectional line of the piezoelectrically driven MEMS mirror scanner according to FIG. 1a,

FIG. 1c a plan view of a piezoelectrically driven MEMS mirror scanner according to a further exemplary embodiment with a metal film,

FIG. 1d a cross-section of the piezoelectrically driven MEMS mirror scanner according to FIG. 1c,

FIG. 1e a plan view of an energy harvester according to an exemplary embodiment,

FIG. 1f a cross-section corresponding to a dashed sectional line of the energy harvester according to FIG. 1e,

FIG. 2a a cross-section of a piezoelectrically driven MEMS mirror scanner in the area of a piezoelectric element with a metal electrode according to the prior art,

FIG. 2b a cross-section of a piezoelectrically driven MEMS mirror scanner with a metal film in the area of a piezoelectric element with a flaw to explain possible errors,

FIG. 2c a cross-section of a further exemplary embodiment of a piezoelectrically driven MEMS mirror scanner without a metal film in the area of a piezoelectric element with a flaw to explain possible errors,

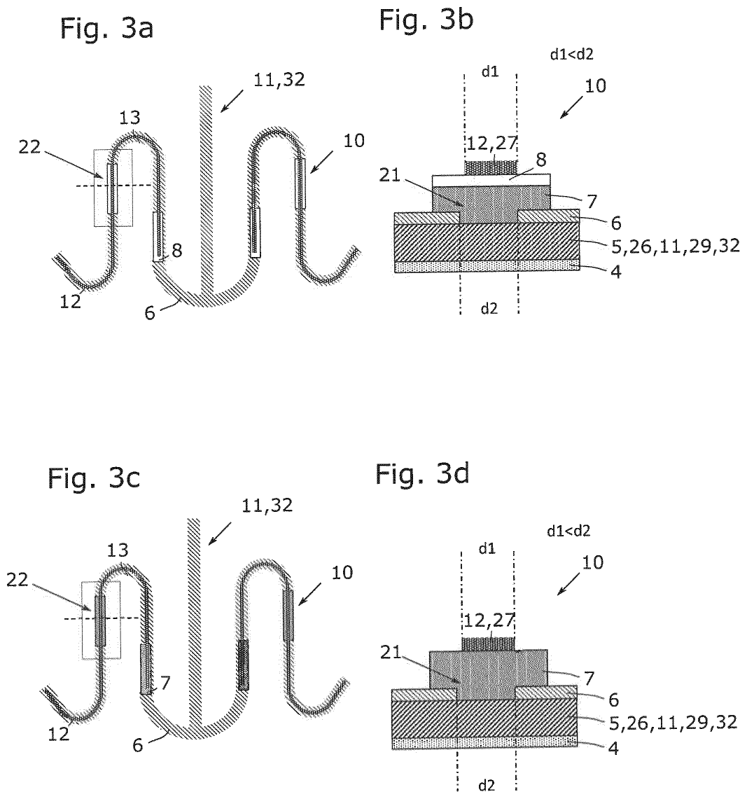

FIG. 3a a plan view of a spring structure of a piezoelectrically driven MEMS mirror scanner of an exemplary embodiment with a metal film to reduce an effect of possible errors,

FIG. 3b a cross-section of an exemplary embodiment corresponding to the dashed sectional line of the piezoelectrically driven MEMS mirror scanner according to FIG. 3a,

FIG. 3c a plan view of a spring structure of a piezoelectrically driven MEMS mirror scanner of a further exemplary embodiment without a metal film to reduce an effect of possible errors,

FIG. 3d a cross-section of an exemplary embodiment corresponding to the dashed sectional line of the piezoelectrically driven MEMS mirror scanner according to FIG. 3c,

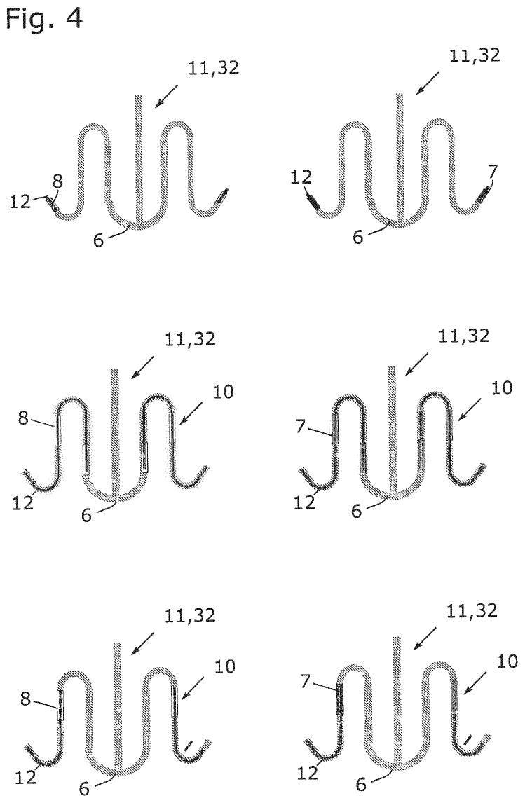

FIG. 4 a plan view of the spring structure of a piezoelectrically driven MEMS mirror scanner with preferred attachment points of piezoelectric elements,

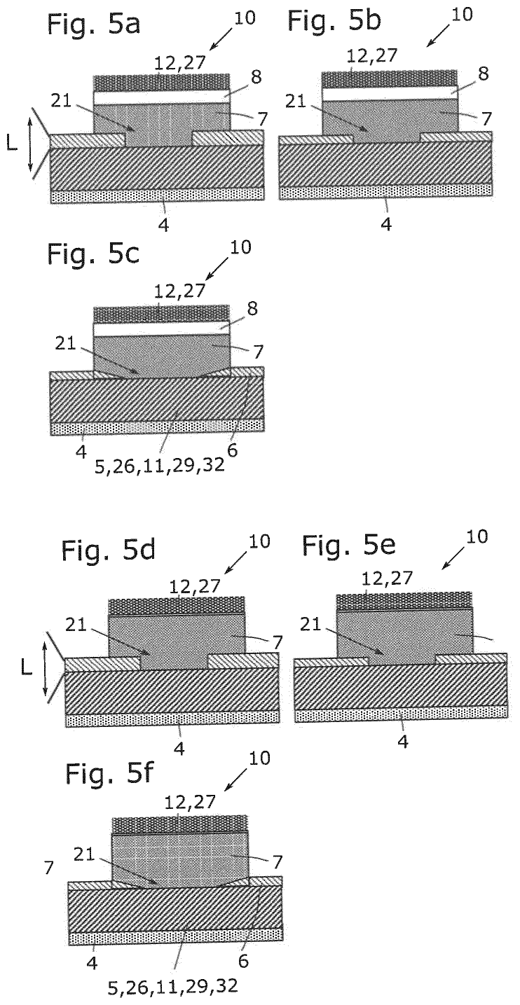

FIG. 5a a cross-section of an exemplary embodiment of the piezoelectrically driven MEMS mirror scanner with a metal film in the area of a piezoelectric element with a dielectric layer,

FIG. 5b a cross-section of an exemplary embodiment of the piezoelectrically driven MEMS mirror scanner with a metal film in the area of a piezoelectric element with a dielectric layer that is thinner than in FIG. 5a,

FIG. 5c a cross-section of an exemplary embodiment of the piezoelectrically driven MEMS mirror scanner with a metal film in the area of a piezoelectric element with a dielectric layer that decreases towards the opening area,

FIG. 5d a cross-section of a further exemplary embodiment of the piezoelectrically driven MEMS mirror scanner without a metal film in the area of a piezoelectric element with a dielectric layer,

FIG. 5e a cross-section of a further exemplary embodiment of the piezoelectrically driven MEMS mirror scanner without a metal film in the area of a piezoelectric element with a dielectric layer that is thinner than in FIG. 5d,

FIG. 5f a cross-section of a further exemplary embodiment of the piezoelectrically driven MEMS mirror scanner without a metal film in the area of a piezoelectric element with a dielectric layer that decreases towards the opening area,

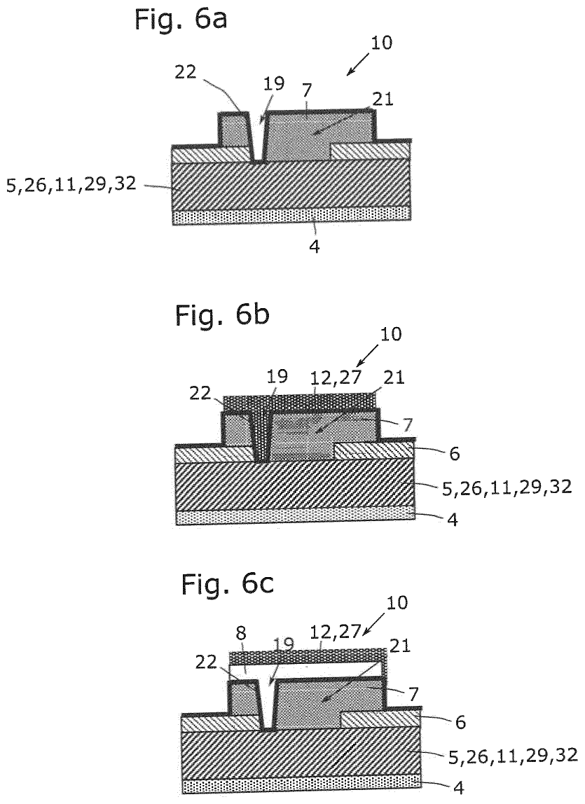

FIG. 6a a cross-section of a further embodiment of a piezoelectrically driven MEMS mirror scanner in the area of a piezoelectric element with an additional passivation layer,

FIG. 6b a cross-section of a further embodiment of a piezoelectrically driven MEMS mirror scanner in the area of a piezoelectric element with an additional passivation layer and a conductive layer film,

FIG. 6c a cross-section of a further embodiment of a piezoelectrically driven MEMS mirror scanner in the area of a piezoelectric element with an additional passivation layer, a metal film and a conductive layer film,

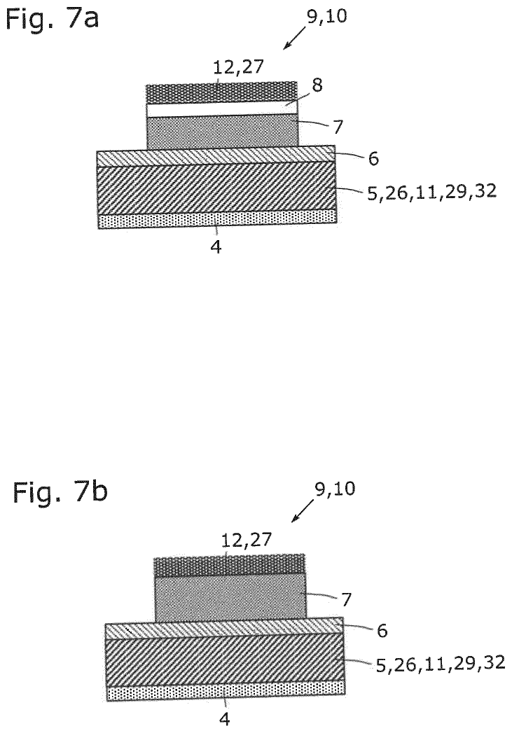

FIG. 7a a cross-section of a further embodiment of a piezoelectrically driven MEMS mirror scanner with a metal film in the area of a piezoelectric element with a full-coverage dielectric layer,

FIG. 7b a cross-section of a further embodiment of a piezoelectrically driven MEMS mirror scanner with a metal film in the area of a piezoelectric element with a full-coverage dielectric layer,

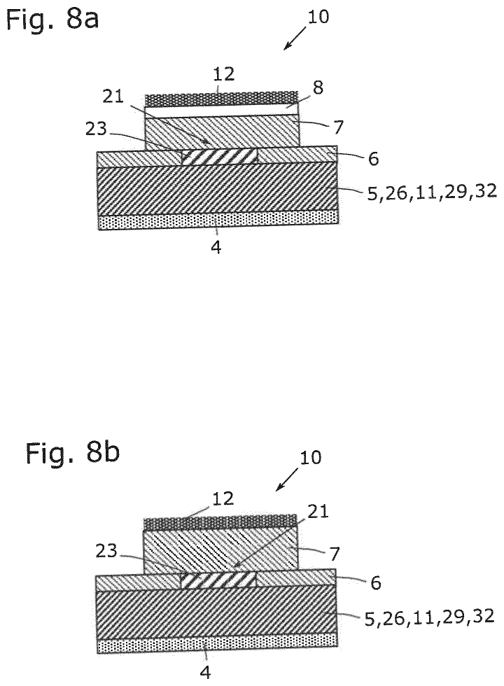

FIG. 8a a cross-section of a further embodiment of a piezoelectrically driven MEMS mirror scanner with a metal film in the area of a piezoelectric element with a filled opening area of a dielectric layer,

FIG. 8b a cross-section of a further embodiment of a piezoelectrically driven MEMS mirror scanner without a metal film in the area of a piezoelectric element with a filled opening area of a dielectric layer,

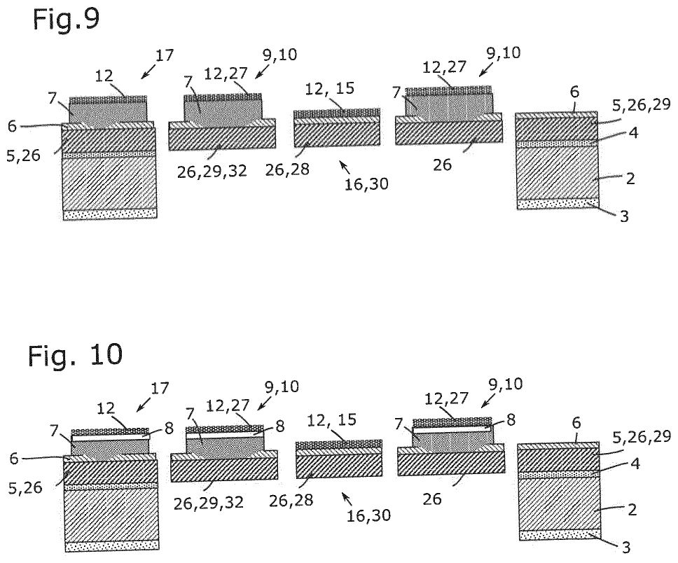

FIG. 9 a cross-section of a further embodiment of a piezoelectrically driven MEMS mirror scanner, wherein a conductive layer film is used as an upper metal contact and a mirror layer,

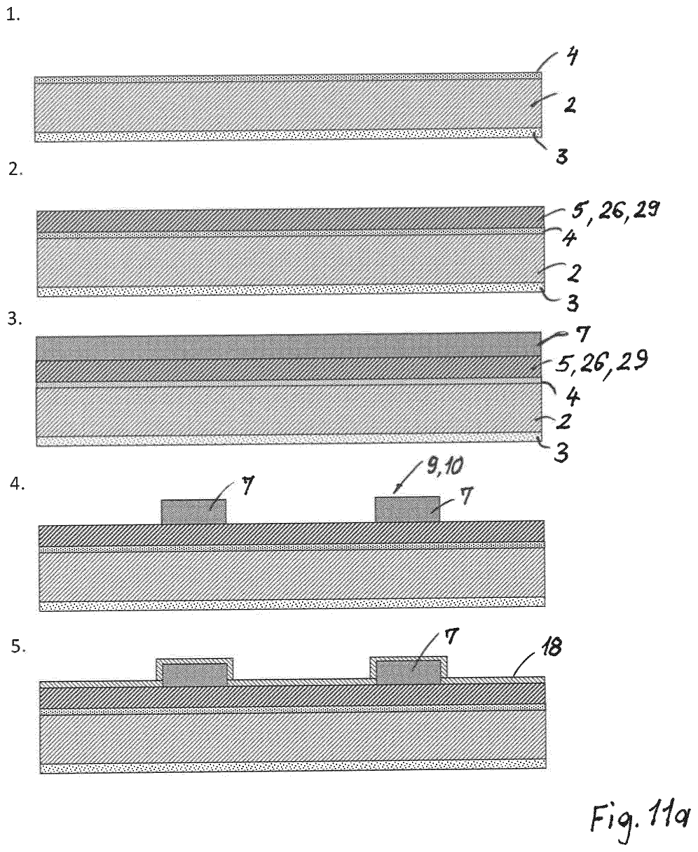

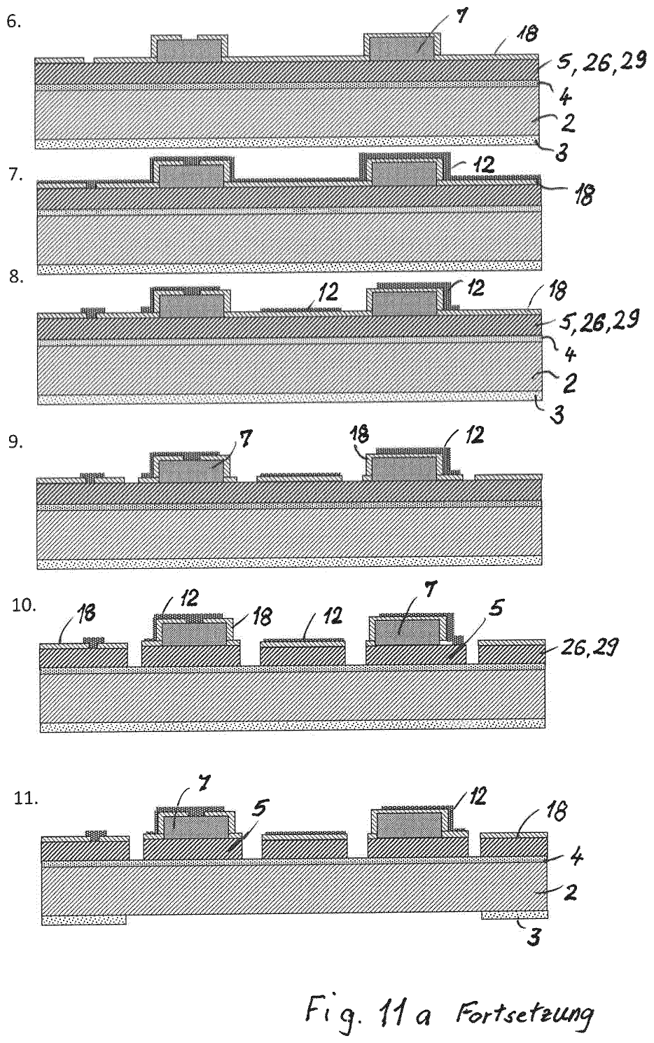

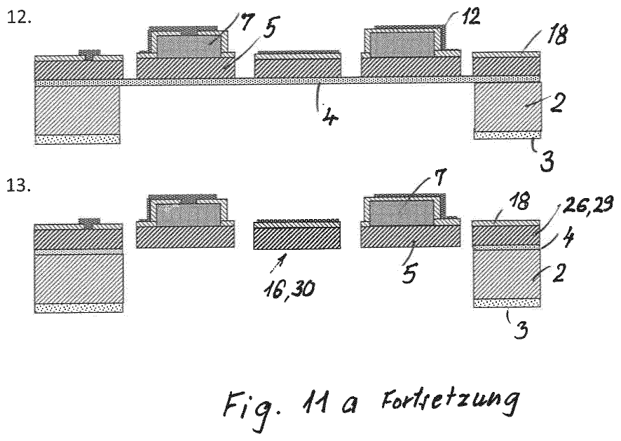

FIG. 10 a cross-section of another embodiment of a piezoelectrically driven MEMS mirror scanner, wherein a conductive layer film and a metal film are used as an upper metal contact and the conductive layer film is used as a mirror layer,

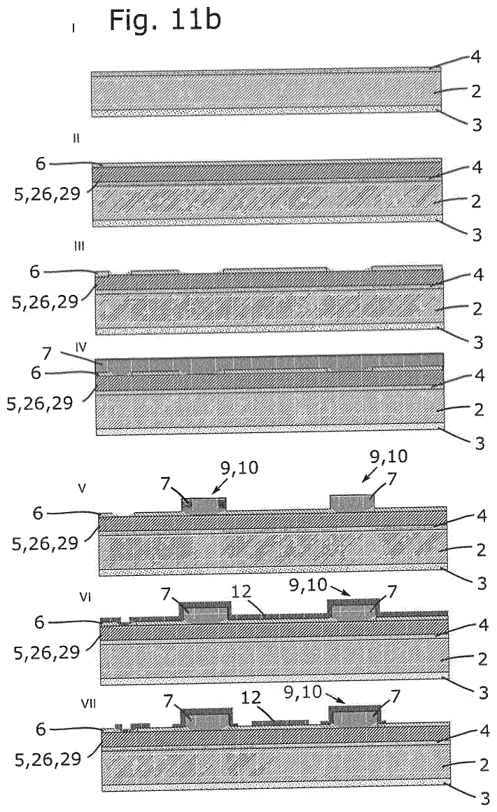

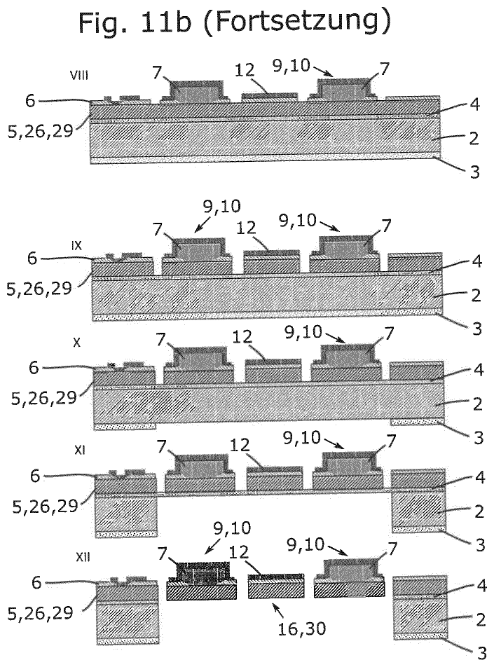

FIG. 11a a production sequence for a piezoelectrically driven MEMS mirror scanner according to FIG. 1b,

FIG. 11b a production sequence for a piezoelectrically driven MEMS mirror scanner with a metal film.

Recurring and similar features of different embodiments are labelled with identical or similar alphanumeric reference signs in the figures.

FIG. 1a shows a plan view and FIG. 1b a cross-sectional view of an exemplary embodiment of a micromechanical component 1, which is formed as a piezoelectrically driven MEMS mirror scanner 150. The plan view shows a simplified layout of the piezoelectrically driven MEMS mirror scanner 150 with its functional areas. A deflection element 16, which is formed in particular as a mirror plate 30, has a carrier layer 28 and a light-reflecting mirror layer 15. The mirror plate 30 is mechanically connected to and suspended from a suspension 32—formed as a spring structure 11. The spring structure 11 is suspended from a holder 17 in the form of a chip frame. Both the mirror plate 30 and the spring structure 11 are defined by cut-outs in the MEMS mirror scanner 150. The spring structure 11 is at least partially covered with a piezoelectric layer 7, in particular piezoelectric elements 10, to create a drive and/or sensing area. At least one detection and/or drive area is defined. In addition, part of the holder 17 may be covered with the piezoelectric layer 7. This allows steps in the area of the holder 17 to be minimized in order to avoid low-resistance connections. In order to apply an electrical voltage to the piezoelectric layer 7, metal bond pads 14 and electrical wiring lines 13 based on a conductive layer film 12 are provided. In a region 9 of the piezoelectric elements 10 labelled piezo region, the conductive layer film 12 forms a second electrode 27 for the piezoelectric elements 10. Electrically separate from this, the conductive layer film 12 additionally contacts a conductive semiconductor layer 26, in particular formed as a polycrystalline silicon layer 29, which forms first electrodes 5 for the piezoelectric elements 10 in the area 9 of the piezoelectric elements 10. However, the silicon layer 29 may also be formed from a monocrystalline silicon.

Furthermore, the conductive layer film 12 forms the light-reflecting mirror layer 15 of the mirror plate 30.

In order to deflect an incoming light beam, an electrical voltage is applied to the metal bond pads 14. An electrical voltage applied to the bond pads 14 leads to a piezoelectric deformation of the piezoelectric layer 7 via the first electrode 5 and the second electrode 27 and an actuation of the piezoelectric element 10. The deformation of the piezoelectric layer 7 of the piezoelectric element 10 causes the spring structure 11 to deflect. The polycrystalline silicon layer 29 of the spring structure 11 also forms the carrier layer 28 of the mirror plate 30 of the MEMS mirror scanner 150. In this way, the mirror plate 30 is mechanically coupled to the spring structure 11 and a deflection of the spring structure 11 leads to a deflection of the mirror plate 30. Depending on the spring structure 11, the mirror plate 30 may rotate in one or two axes, whereby a light beam is controlled and/or detected in one or two dimensions. The mechanical behaviour of the MEMS mirror scanner is defined on the one hand by the layer thicknesses and on the other hand by the clearances generated by means of depth etching.

FIG. 1b shows a cross-section of FIG. 1a to illustrate the functional areas of the piezoelectrically driven MEMS mirror scanner 150.

The holder 17 surrounding the mirror plate 30, which in the present case is formed as a chip frame, has in cross-section a lower passivation layer 3, a silicon substrate 2, an intermediate passivation layer 4, the polycrystalline silicon layer 29 and an upper passivation layer 18. It is possible that the MEMS mirror scanner 150 does not have a lower passivation layer 3. The upper passivation layer 18 serves as an electrical insulator and covers the piezoelectric layer 7 in the piezo area 9, which is arranged directly on the polycrystalline silicon layer 29 (conductive semiconductor layer 26). The silicon substrate 2 is configured to keep the holder 17 or the chip frame dimensionally stable.

The piezoelectric elements 10 have a layered structure, starting from one side of the silicon substrate 2, consisting of polycrystalline silicon layer 29, piezoelectric layer 7, upper passivation layer 18 and the at least partially covering and/or partially opened further conductive layer film 12. The polycrystalline silicon layer 29 serves in the piezo area 9 as the first electrode 5 for controlling the piezoelectric elements 10 and/or for detecting a deflection state of the spring structure 11 and/or the mirror plate 30. Furthermore, the polycrystalline silicon layer 29 or conductive semiconductor layer 26 is additionally set up to form the spring structure 11 of the MEMS mirror scanner 150.

In order to enable elastic deformation of the spring structure 11, a layered structure of the spring structure 11, starting from one side of the silicon substrate 2, comprises the polycrystalline silicon layer 29 and the upper passivation layer 18. It is also possible that the spring structure 11 has the intermediate passivation layer 4 below the polycrystalline silicon layer 29.

The mirror plate 30 has a layered structure, starting from one side of the silicon substrate 2, consisting of a polycrystalline silicon layer 29, an upper passivation layer 18 (which may also be omitted in the area of the mirror plate 30) and a conductive layer film 12. In the mirror plate 30, the polycrystalline silicon layer 29 serves as a carrier layer 28 and the conductive layer film 12 serves as the light-reflecting mirror layer 15. In other embodiments, it may be provided that the piezoelectric elements 10 and the mirror plate 30 have the intermediate passivation layer 4 below the polycrystalline silicon layer 29.

FIG. 1c shows a plan view and FIG. 1d a cross-sectional view of a further exemplary embodiment of a piezoelectrically driven MEMS mirror scanner 150. The exemplary embodiment in FIG. 1c and FIG. 1d is identical to the exemplary embodiment in FIG. 1a and FIG. 1b, but here a metal film 8 is provided which covers the piezoelectric layer 7. It may be provided that the metal film 8 is set up to serve as a masking layer for a further structuring process, in particular for masking the piezoelectric elements 10. If the metal film 8 is omitted, a sacrificial layer may be used as a masking for the further structuring process, which is then removed and with which the exemplary embodiment of FIG. 1a and FIG. 1b may be realized.

Furthermore, a dielectric layer 6 is arranged here on the conductive semiconductor layer 26 or the polycrystalline silicon layer 29 and is partially open to the conductive semiconductor layer in the piezo region 9.

FIG. 1e shows a plan view and FIG. 1f a cross-sectional view of a further exemplary embodiment of a micromechanical component 1, which is formed as an energy harvester 200. The plan view shows a simplified layout of the energy harvester. A deflection element 16, formed as a beam element 31, is mechanically connected to a suspension 32 and the suspension 32 is attached to a holder 17 formed as a chip frame. The beam element 31 is at least partially covered with a piezoelectric layer 7, in particular a piezoelectric element 10, to create a sensing area. Of course, a plurality of piezoelectric elements 10 may also be provided on the beam element 31. At least one sensing area is defined. In addition, part of the holder 17 may be covered with the piezoelectric layer 7. This allows steps in the area of the holder 17 to be minimized in order to avoid low-resistance connections.

Both the beam element 31 and the suspension 32 are defined by clearances in the energy harvester 200. The beam element 31 may be deflected via the suspension 32 by means of oscillations and/or vibrations, in particular ambient vibrations. A sensitivity to different frequency spectra and/or frequency bands may be set by means of a geometry of the energy harvester 200, in particular a spatial geometry of the beam element 31, the suspension 32 and the holder 17. The oscillations and/or vibrations are converted into an electrical voltage by the piezoelectric element 10, which is located on the beam element 31, wherein in particular a crystal lattice distortion of elementary cells of the piezoelectric layer 7 is utilized by the piezoelectric effect. This electrical voltage is tapped via metal bond pads 14 and metal electrical wiring lines 13 and may be stored and/or utilized by a suitable circuit, in particular consisting of capacitors and resistors. The conductive layer film 12 at least partially covers the piezoelectric layer 7. In the area 9 of the piezoelectric element 10, the conductive layer film 12 forms the second electrode 27 for the piezoelectric element 10. Electrically separate from this, the conductive layer film 12 also contacts the conductive polycrystalline silicon layer 29, which forms the first electrode 5 for the piezoelectric element 10 in the area 9 of the piezoelectric element 10.

FIG. 1f shows a cross-section of FIG. 1e to illustrate the functional areas of the energy harvester 200.

In cross-section, the holder 17 surrounding the energy harvester 200 has a lower passivation layer 3, a silicon substrate 2, an upper passivation layer 4, a polycrystalline silicon layer 29 and a dielectric layer 6. The dielectric layer 6 is open in some areas to allow direct layer contact between the conductive layer film 12 and the polycrystalline silicon layer 29. As above, the dielectric layer 6 serves as an electrical insulator to prevent low-resistance connections. The silicon substrate 2 is configured to keep the holder 17 of the energy harvester 200 dimensionally stable. The polycrystalline silicon layer 29 serves as the first electrode 5 for the piezoelectric elements 10 in the area 9. Here too, the dielectric layer shown may be replaced by an upper passivation layer, similar to the layer 18 of FIG. 1b, covering the second electrode 27 in the piezo region 9, and the piezoelectric layer 7 then contacts the polycrystalline silicon layer 29.

The piezoelectric element 10 has the polycrystalline silicon layer 29, optionally at least partially the dielectric layer 6, the piezoelectric layer 7 and an at least partially covering further conductive layer film 12, optionally also the upper passivation layer. As with the MEMS mirror scanner 150, the polycrystalline silicon layer 29 forms here both the first electrode 5 and the suspension 32.

The beam element 31 comprises a layered structure consisting of a lower passivation layer 3, a silicon substrate 2, an intermediate passivation layer 4, a polycrystalline silicon layer 29 and a dielectric layer 6 or an upper passivation layer. The silicon substrate 2 is set up to serve as an inertial mass for the beam element 31. In this way, an inertia mass of the beam element 31 may be increased in order to advantageously convert the ambient vibrations into an oscillation, vibration and/or deflection of the beam element 31. In particular, sensitivity to different frequency spectra of the ambient vibration may be adjusted by means of a weight of the inertial mass. However, at least in an area surrounding the region 9 of the piezoelectric element 10, the beam element 31 has no lower passivation layer 3, no silicon substrate 2 and no intermediate passivation layer 4 to enable elastic deformation of the piezoelectric layer 7.

As already introduced above, FIG. 2a shows a detail of a piezoelectric element of a piezoelectrically driven MEMS mirror scanner 100 according to the prior art with an upper passivation 4, a polycrystalline silicon layer 29, a conventional metal first electrode 20, a piezoelectric layer 7 and a second electrode 27 and, by way of comparison, FIG. 2b shows a piezoelectrically driven MEMS mirror scanner 150 with a first electrode 5 made of polycrystalline silicon according to an embodiment of the present invention. Compared to FIG. 2a, a first metal electrode 20 is not used in FIG. 2b. Due to the high conductivity of polycrystalline silicon, in particular doped polycrystalline silicon, an increase in the operating voltage of the piezoelectrically driven MEMS mirror scanner 150 is only slight compared to the conventional embodiment shown in FIG. 2a. Dispensing with the metal first electrode 20 may reduce the complexity and cost of producing the piezoelectrically driven MEMS mirror scanner.

However, if the piezoelectric layer 7 is in direct contact with the polycrystalline silicon layer 29, as shown in FIG. 2c, this leads to low-resistance electrical connections, particularly at the stepped edges of an opening region 21 of the dielectric layer 6. The reasons for the low-resistance connections are flaws and/or crystal defects 19 due to poor growth behaviour in the opening region 21 and/or material fatigue due to high loads during operation. The following describes embodiments of how low-resistance connections may be prevented.

FIG. 3a shows a plan view of the spring structure 11, analogous to FIG. 1a. The plan view in FIG. 3a shows curved areas of the spring structure 11 with a small radius of curvature and relatively straight areas of the spring structure 11 with a large radius of curvature. In a preferred embodiment, different areas of the spring structure 11 have different curvatures, in particular right-hand curvatures and left-hand curvatures. The spring structure 11 is mechanically connected to the mirror plate 30 via a rectilinear area of the spring structure 11.

The piezoelectric elements 10 are located at positions on the spring structure 11 with a slight curvature—in particular a slight curvature outside a plane parallel to the substrate plane—during a deflection of the spring structure 11. The positions on the spring structure 11 with a low curvature during the deflection of the spring structure are characterized by the fact that they exhibit a low deformation during operation or deflection of the spring structure 11. Based on simulations, for example mechanical finite element analysis, an area of the spring structure 11 with a large curvature during operation may be identified. These areas should not contain any piezoelectric elements 10 in order to prevent low-resistance connections due to material fatigue.

Furthermore, the piezoelectric elements 10 should be located at positions with optimum voltage behaviour, in particular at positions with a high positive or high negative mechanical voltage. In this way, the actuation and/or detection efficiency may be maximized.

FIG. 3b shows a cross-sectional view of a piezoelectric element 10 of a MEMS mirror scanner 150. A dotted line in FIG. 3a represents a cross-sectional area of FIG. 3b. The embodiment in FIG. 3b is similar to the embodiment of the piezoelectric element in FIG. 1d, but a width d1 of the second electrode 27 is smaller than an opening d2 of the dielectric layer 6. The opening d2 of the dielectric layer defines the width of the first electrode 5. Flaws and/or crystal defects within the piezoelectric layer 7 occur more frequently in an edge region of the opening region 21, in particular at stepped edges of the dielectric layer 6. The flaws and/or crystal defects typically continue in a direction perpendicular to a silicon substrate plane. Because the width d1 of the second electrode 27 and thus the area of the second electrode 27 is smaller than an opening d2 and thus the opening area of the dielectric layer 6, the second electrode 27 does not lie directly over the edge area of the opening region of the first electrode 5. In this way, the conductive layer film 12 of the second electrode 27 may be prevented from penetrating into the flaws. The penetration of the conductive layer film 12 of the second electrode 27 into flaws may in turn lead to undesirable low-resistance connections.

FIG. 3c shows a plan view analogous to FIG. 3a, and FIG. 3d a cross-sectional view of FIG. 3c analogous to FIG. 3b. As in FIG. 1c and FIG. 1d, however, the metal film 8 has been omitted in FIG. 3c and FIG. 3d.

As in FIG. 3a and FIG. 3c, FIG. 4 shows plan views of the spring structures 11 with (left) and without (right) metal film 8 of a piezoelectrically driven MEMS mirror scanner 150. In particular, FIG. 4 shows further advantageous positions of the piezoelectric elements 10 on the spring structure 11. The advantageous positions may be determined, for example (as already explained above), by simulations, in particular mechanical finite element analyses.

However, if, as shown in FIG. 5a (and analogously in FIG. 5d, but without metal film 8), the width of the second electrode 27 is greater than the opening of the dielectric layer 6, crystal defects at the stepped edges of the opening of the dielectric layer 6 must be suppressed. In this embodiment, a crystal defect could lead to a low-resistance electrical connection. Reducing a step height L, as shown in FIG. 5b (and analogously in FIG. 5e, but without metal film 8), on the basis of a very thin dielectric layer 6, for example ₁₀ nm Al₂O₃, may lead to a lower defect density or a lower spatial development of the crystal defects at the stepped edges of the dielectric layer 6. This therefore minimizes the likelihood of metal, in particular the conductive layer film 12, penetrating into the flaws and/or crystal defects, which would lead to low-resistance connections between the second electrode 27 and the first electrode 5. As shown in FIG. 5c (and analogously in FIG. 5f, but without metal film 8) and as may also be seen in FIG. 1d, the step height I may also be minimized by reducing the thickness of the dielectric layer 6 towards the opening region 21. In particular, a linear or quasi-linear decrease in the layer thickness of the dielectric layer 6 to a vanishing layer thickness may be provided. A decrease in the layer thickness of the dielectric layer 6 may be realized by lithographic structuring processes, among other things.

In order to prevent low-resistance connections, a further embodiment may be provided. FIGS. 6a, 6b and 6c show an embodiment similar to FIG. 5a, but in which an upper passivation layer 22, for example Al₂O₃, additionally covers the piezoelectric layer 7. If, as shown in FIG. 6b, the upper passivation layer 22 is covered with the conductive layer film 12, the passivation layer 22 serves as an electrical insulation barrier. This may prevent galvanic contact despite the presence of a crystal defect 19. FIG. 6c shows an embodiment analogous to FIG. 6b, but in which a metal film 8 is additionally used and in this embodiment material from the metal film 8 penetrates into the crystal defect 19.

Other options for preventing stepped edges of the dielectric layer are to fill the opening region 21 or to dispense with an opening in the dielectric layer 6. In FIG. 7a (and analogously in FIG. 7b, but without metal film 8), at least in the area 9 of the piezoelectric elements 10, the polycrystalline silicon layer 29 is covered over its entire surface with the dielectric layer 6, for example with SiO₂. This means that the dielectric layer 6 has no opening to the polycrystalline silicon layer 29. This means that no step occurs and the piezoelectric layer 7 may grow under optimum planarity conditions. In this way, flaws and/or crystal defects may be suppressed.

FIG. 8a (and analogously FIG. 8b, but without metal film 8) shows that in another embodiment, polycrystalline silicon 23 is deposited or grown in the opening region 21 of the dielectric layer 6 and leads to planarization. The polycrystalline silicon 23 in the opening region 21 may be realized in particular by selective growth and/or masking. Another approach to realize the polycrystalline silicon 23 in the opening region 21 may be the growth of silicon based on an epitaxy process and a subsequent selective, chemical and mechanical polishing process for planarization. Due to the planarization, the formation of a flaw and/or a crystal defect may be prevented, which reduces the probability of a low-resistance connection.

As an alternative to the embodiments described above, as shown in FIG. 9, it may be provided that the piezoelectric layer 7 is wider than in the embodiment of FIG. 1d and covers the holder 17 at least in some areas. This allows steps, in particular steps of the conductive layer film 12 in the area of the holder 17, to be minimized in order to avoid low-resistance connections. Structuring and/or masking of the piezoelectric layer 7 in FIG. 9 may be achieved by a sacrificial layer, which is subsequently removed. FIG. 10 shows a further embodiment with an extended piezoelectric layer 7, which covers the holder 17 at least in some areas. Here, the metal film 8 is used as a mask for the subsequent structuring process of the piezoelectric layer 7.

FIG. 11a shows an exemplary production sequence of a piezoelectrically driven MEMS mirror scanner 150.

In a first step 1, a silicon substrate 2, in particular a crystalline bulk silicon substrate, is passivated. A lower passivation layer 3 and an intermediate passivation layer 4 are produced by wet and/or dry oxidation.

In a second step 2, doped polycrystalline silicon is deposited on the intermediate passivation layer 4. The deposition process takes place in an epitaxial deposition system, for example. The resulting polycrystalline silicon layer 29 typically has a thickness of between 1 μm and 300 μm.

Alternatively, when using monocrystalline silicon, so-called conventionally available SOI wafers may be used and may thus replace step 2. In this process, another crystalline silicon wafer is bonded onto the previously applied oxide layer and ground back to any desired layer thickness.

Subsequently, in step 3, a deposition, in particular a physical vapour deposition (PVD), of a piezoelectric layer 7 takes place. Here, the piezoelectric layer 7 should have high piezoelectric and/or pyroelectric and/or ferroelectric constants. Ceramic ferroelectrics or piezoelectrics, such as aluminium nitride (AlN) or lead zirconate titanate (PZT), are particularly suitable for this purpose. However, semi-crystalline polymer materials such as PVDF (polyvinylidene fluoride (CF2-CH2)n) are also suitable.

In a fourth step 4, the piezoelectric layer 7 is structured in a plasma and/or wet-chemical process. The piezoelectric layer 7 may be wet-etched—for example with phosphoric acid for AlN—or dry-etched. A photolithography mask is used to structure the piezoelectric layer 7. The piezo areas 9 define the piezoelectric elements 10 and a drive and/or sensing area of the MEMS mirror scanner 150.

In step 5, a passivation layer 18 is deposited over the structured piezoelectric layer 7 and the polycrystalline silicon layer 29, wherein the passivation layer is structured in a subsequent step 6, as is also shown by way of example in the region of a piezo region 9. PECVD SiO2 may be used as a passivation layer, but any material that is electrically non-conductive and also has a relatively high dielectric strength may be used, for example silicon nitride Si3N4, Al2O3 aluminium oxide.

In a step 7, the conductive layer film 12, consisting in particular of aluminium, but also other materials such as Cu, Mo, etc., is deposited on the structured passivation layer 18.

In a step 8, the conductive layer film 12 is structured via a photolithography mask using dry etching, for example chlorine-based plasma etching or phosphoric acid-based wet etching. The conductive layer film 12 forms the wiring lines 13, the bond pads 14 and, if necessary, a light-reflecting mirror layer 15. The photolithography mask is then removed using a plasma or wet-chemical process.

If necessary, it may be possible to introduce a further process step to increase the reflective properties in the area of the mirror plate, for example by means of a further metallization and structuring step.

In a step 9, the upper passivation layer 18 is structured by dry etching, in particular fluorine-based plasma etching using a photolithography mask.

In a step 10, using the photolithography mask from step 9, deep reactive ion etching (DRIE) is used for structuring of the polycrystalline silicon layer 29. In another embodiment, the intermediate passivation layer 4 may additionally be at least partially opened in the same step or in an additional process step. The photolithography mask is then removed using a plasma or wet-chemical process. In this step, the mechanical spring structure 11 and the mirror plate 30 are defined.

In a step 11, the lower passivation layer 3 is opened in some areas using a dry etching process, in particular fluorine-based plasma etching via a photolithography mask.

In a step 12, the existing photolithography mask from step 11 or a new photolithography mask for deep reactive ion etching is used to structure the silicon substrate 2.

Lastly, in a step 13, the intermediate passivation layer 4 is removed in some areas. The resulting clearances define the holder 17, the mirror plate 30 and the spring structure 11. After a final plasma or wet-chemical photoresist removal step, the production of the piezoelectrically driven MEMS mirror scanner 150 is complete.

If necessary, the lower passivation layer 3 may be completely removed in step 11.

FIG. 11b shows a further exemplary embodiment.

Step I corresponds to step 1 from FIG. 11a.

In a second step II, doped polycrystalline silicon is deposited on the passivation layer 4 in accordance with step 2 from FIG. 11a. A further passivation of the polycrystalline silicon layer 29 is then carried out to form a dielectric layer 6. The dielectric layer 6 may, for example, be applied from the gas phase in the form of silicon dioxide. As described for FIG. 11a, an SOI wafer may also be used here.

In a third step III, the dielectric layer 6 is first opened in some areas using a photolithographic mask and an etching process, in particular fluorine-based plasma etching and/or wet etching, in particular with hydrofluoric acid. The photolithography mask is removed by a plasma and/or wet chemical process. This is followed by deposition, in particular physical vapour deposition (PVD), of a piezoelectric layer 7. Here, the piezoelectric layer 7 should have high piezoelectric and/or pyroelectric and/or ferroelectric constants. Ceramic ferroelectrics or piezoelectrics, such as aluminium nitride (AlN) or lead zirconate titanate (PZT), are particularly suitable for this purpose. However, semi-crystalline polymer materials such as PVDF (polyvinylidene fluoride (CF2-CH2) n) are also suitable. A metal film 8 is deposited on the piezoelectric layer 7 and is metallic. In particular, molybdenum deposited by means of physical vapour deposition may be provided as a metal film 8. In another embodiment, however, a semiconductor material such as polycrystalline silicon may be used instead of the metal film 8.

In a fourth step IV, the metal film 8 is structured using a photolithography mask and an etching process. If the metal film 8 consists of molybdenum, a wet-etching process based on phosphoric acid is used.

In a fifth step V, as in step 3 of FIG. 11a, the piezoelectric layer 7 is structured. However, the metal film 8 serves as a hard mask for structuring the piezoelectric layer 7.

Step VI corresponds to step 7 of FIG. 11a and step Vii to step 8 of FIG. 11a

In an eighth step VIII, the dielectric layer 6 is structured by dry etching, in particular fluorine-based plasma etching using a photolithography mask.

Step IX corresponds to step 10 from FIG. 11a, wherein the photolithography mask from step VIII is used here.

Steps X, XI and XII correspond to steps 11 12 and 13 of FIG. 11a.

If no metal film 8 is used, a sacrificial layer or auxiliary layer is applied to the piezoelectric layer 7 instead of the metal film 8 in step IV. This sacrificial layer or auxiliary layer serves as a masking for a structuring process of the piezoelectric layer 7. This sacrificial layer or auxiliary layer is removed again after the structuring process and may correspond to photoresist, for example.

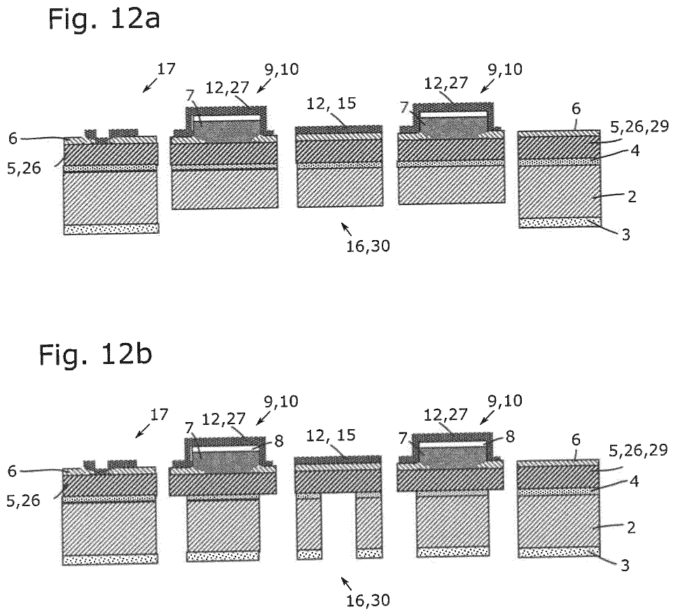

FIGS. 12a and 12b show an alternative embodiment to FIG. 1d. In these embodiments, at least part of the silicon substrate 2 is left below the polycrystalline silicon layer 29 in the region of the deflection element 16 and the piezo regions 9. This allows a stiffening of the deflection element 16 to be achieved, which may have an effect on a dynamic deformation of the deflection element 16. In particular, this may lead to less deformation of the deflection element 16. Various structures of the silicon substrate 2, in particular honeycomb-like structures, may be provided. Furthermore, an overall layer thickness of the deflection element 16 may be varied, in particular to vary a resonance frequency of the micromechanical component.

List of reference signs:

| | |
|---|---|
| 1 | Micromechanical component |
| 2 | Silicon substrate |
| 3 | Lower passivation layer |
| 4 | Intermediate passivation layer |
| 5 | First electrode |
| 6 | Dielectric layer |
| 7 | Piezoelectric layer |
| 8 | Metal film |
| 9 | Piezo ranges |
| 10 | Piezoelectric element |
| 11 | Spring structure |
| 12 | Conductive layer film |
| 13 | Metal electrical wiring cables |
| 14 | Bond pads |
| 15 | Light-reflecting mirror layer |
| 16 | Deflection element |
| 17 | Holder |
| 18 | Upper passivation layer |
| 19 | Crystal defect |
| 20 | Conventional metal first electrode |
| 21 | Opening region |
| 22 | Passivation layer |
| 23 | Polycrystalline silicon |
| 26 | Conductive semiconductor layer |
| 27 | Second electrode |
| 28 | Carrier layer |
| 29 | Polycrystalline silicon layer |
| 30 | Mirror plate |
| 31 | Beam element |
| 32 | Suspension |
| 100 | Conventional piezoelectrically driven MEMS mirror scanner |
| 150 | MEMS mirror scanner |
| 200 | Energy harvester |

1. A micromechanical component having a layered structure and at least one piezoelectric element containing a first electrode and a second electrode for at least one of generating or detecting deflections of a deflection element connected to a holder, wherein the layered structure comprises:
a silicon substrate;
a conductive semiconductor layer;
a piezoelectric layer; and
a conductive layer film, wherein the conductive semiconductor layer forms the first electrode, wherein the conductive layer film forms the second electrode of the at least one piezoelectric element, and wherein the conductive semiconductor layer also forms a carrier layer for the deflection element.

2. The micromechanical component according to claim 1, wherein the conductive semiconductor layer, the piezoelectric layer and the conductive layer film are formed in layers in different layer planes, wherein the different layer planes have a layer sequence starting from one side of the silicon substrate of:
the conductive semiconductor layer;
the piezoelectric layer; and
the conductive layer film, wherein at least one of: an additional semiconductor laver, an insulator layer, or a metal layer is inserted between one or more of the conductive semiconductor layer, the piezoelectric layer, or the conductive layer film.

3. The micromechanical component according to claim 1, wherein the deflection element includes a spring structure connected to the holder and a mirror plate suspended from the spring structure, and wherein the conductive semiconductor layer substantially simultaneously forms the carrier layer of at least one of the mirror plate or the spring structure.

4. The micromechanical component according to claim 3, wherein the conductive layer film also forms a light-reflecting mirror layer or the mirror plate.

5. The micromechanical component according to claim 3, wherein the spring structure comprises the conductive semiconductor layer, the piezoelectric layer, and the conductive layer film at least in some areas.

6. The micromechanical component according to claim 5, wherein the conductive semiconductor layer, the piezoelectric layer and the conductive layer film of the spring structure are located at positions with small bending radii when the spring structure is deflected from a plane to a rest position.

7. The micromechanical component according to claim 1, wherein the deflection element is formed as a beam element suspended on at least one side, wherein the conductive semiconductor layer also forms the carrier layer of the beam element.

8. The micromechanical component according to claim 7, wherein the beam element comprises the conductive semiconductor layer, the piezoelectric layer, and the conductive layer film at least in some areas.

9. The micromechanical component according to claim 7, wherein the beam element comprises the silicon substrate at least in some regions, wherein the silicon substrate is arranged in such a way that it forms an inertial mass for the beam element.

10. The micromechanical component according to claim 1, wherein a passivation layer is arranged at least partially on the piezoelectric layer.

11. The micromechanical component according to claim 1, wherein the piezoelectric layer is arranged on the conductive semiconductor layer.

12. The micromechanical component according to claim 1, wherein a dielectric layer is arranged between the conductive semiconductor layer and the piezoelectric layer, at least in some areas.

13. The micromechanical component according to claim 12, wherein the conductive semiconductor layer is separated from the piezoelectric layer by a dielectric layer, wherein the dielectric layer is formed with full coverage or in regions with an opening area to the conductive semiconductor layer.

14. The micromechanical component according to claim 13, wherein the opening area of the dielectric layer is filled with silicon.

15. The micromechanical component according to claim 1, wherein the conductive semiconductor layer comprises silicon, in particular polycrystalline silicon.

16. The micromechanical component according to claim 1, wherein a metal film is arranged between the piezoelectric layer and the conductive layer film, at least in some areas.

17. The micromechanical component according to claim 1, wherein, the holder is a chip frame of the micromechanical component.

18. The micromechanical component according to claim 1, wherein, for stabilization, a dielectric layer is applied to the second electrode formed by the conductive layer film.

19. A method for producing a micromechanical component, the method comprising:
depositing a conductive semiconductor layer on a silicon substrate;
depositing a piezoelectric layer;
depositing a conductive layer film, serving as second electrode, on the piezoelectric layer; and
structuring a deflection element by a masking process of the silicon substrate, of the conductive semiconductor layer, of the piezoelectric layer, and of the conductive layer film by lithographic processes, wherein the conductive semiconductor layer is used as a first electrode for the piezoelectric layer and also as a carrier layer for the deflection element.

20. The method for producing a micromechanical component according to claim 19, wherein a metal film is deposited on the piezoelectric layer after the piezoelectric layer has been deposited.

21. The method for producing a micromechanical component according to claim 20, wherein the metal film is used as a masking for a later structuring process.

22. The method for producing a micromechanical component according to claim 19, wherein an auxiliary or sacrificial layer is deposited on the piezoelectric layer after the piezoelectric layer has been deposited and is used as a masking for a later structuring process.

23. The method for producing a micromechanical component according to claim 22, wherein the auxiliary or sacrificial layer is formed as a hard mask of silicon nitride (SiN).

24. The method for producing a micromechanical component according to claim 19, wherein a passivation layer is deposited on the piezoelectric layer after the piezoelectric layer has been deposited.

25. The method for producing a micromechanical component according to claim 19, wherein the silicon substrate is formed as an oxidized silicon substrate.

26. The method for producing a micromechanical component according to claim 19, wherein the masking process of the silicon substrate is performed in such a way that the silicon substrate remains at least partially in a region of the deflection element.
